(19) United States
(12) Patent Application Publication
(10) Pub. No.: US 2010/0123258 A1
(43) Pub. Date: May 20, 2010

(54) Low Temperature Board Level Assembly Using Anisotropically Conductive Materials

(76) Inventors: Myung Jin Yim, Chandler, AZ (US); Jason Brand, Placerville, CA (US)

Correspondence Address: TROP, PRUNER & HU, P.C., 1616 S. VOSS ROAD, SUITE 750, HOUSTON, TX, 77057-2631, US

(21) Appl. No.: 12/271,077

(22) Filed: Nov. 14, 2008

(51) Int. Cl. H01L 23/12; B32B 37/12

(52) U.S. Cl. 257/783; 156/325; 257/E23.003

(57) ABSTRACT

An integrated circuit may be secured to a substrate using an anisotropically conductive adhesive that may be cured at a temperature of less than 150° C. In some embodiments, an acrylic resin with embedded metallic particles may be used as the anisotropically conductive adhesive. In some embodiments, the board level reliability of the resulting product may be improved through the use of the anisotropically conductive adhesive that may be cured at a temperature of less than 150° C.

### BACKGROUND

This relates generally to securing components to substrates. In the formation of electronic devices, integrated circuits are typically coupled to a substrate, such as printed circuit boards, flexible film interconnects, sockets, and the like.

In the formation of electronic devices, integrated circuits are typically coupled to substrates. Techniques for joining components to substrates include surface mounting, soldering, and frictional connections. Soldering involves the application of relatively high heat to join contacts using solder. Surface mounting also involves temperatures above 180° C. and the softening of solder-like materials to cause heat-based joints. Frictional connections involve the use of pins or other mechanical components which frictionally engage sockets or the like.

Each of these connection techniques has disadvantages in terms of board level reliability. Surface mount techniques may be subject to thermally induced cracking or cracking due to dropping the component. Solder techniques involve sufficiently high temperatures that may cause damage to some components to be joined. Frictional securement may raise reliability problems because the joints may come undone.

### BRIEF DESCRIPTION OF THE DRAWINGS

FIG. 1 is an enlarged, cross-sectional view of an integrated circuit in the process of being secured to a board in accordance with one embodiment;

FIG. 2 is an enlarged, cross-sectional view at a subsequent stage;

FIG. 3 is an enlarged, cross-sectional view at still a subsequent stage;

FIG. 4 is a greatly enlarged, cross-sectional view of the two components after joinder in accordance with one embodiment; and

FIG. 5 is a greatly enlarged, partial depiction of the connection between a solder ball and a pad in accordance with one embodiment.

### DETAILED DESCRIPTION

In accordance with some embodiments, integrated circuits may be mounted on substrates using an anisotropically conductive adhesive. An anisotropically conductive adhesive is a material that, prior to the application of pressure, is non-conductive. It may be formed of a non-conductive resin base with electrically conductive particles dispersed therein. The size and concentration of the electrically conductive particles is tailored so that normally the material is not conductive prior to the application of pressure. This means that the conductive particles do not touch prior to the application of compressive force to two components to be joined.

In accordance with some embodiments, the resin system used in the anisotropically conductive adhesive is one that cures at a temperature of 150° C. or less. Particularly, it is desirable for the cure to occur at a temperature of 150° C. or less, in less than 15 seconds or at still lower temperatures even if longer cure times are needed. The use of low temperature and anisotropically conductive materials means that the board level interconnects can be accomplished in a fashion that reduces the heat related damage to the components to be joined in some embodiments. This makes the technique particularly amenable to joining integrated circuits that are heat sensitive, such as phase change memories, to substrates.

The type of electrical contact between the integrated circuit and the board is subject to considerable variation.

For example, solder balls, bumps, or protrusions may be used on one component that mate with planar lands or other structures on the other component. Generally, it is advantageous to have a protrusion on one component and a flat surface to be joined on the other component. However, the present invention is not so limited.

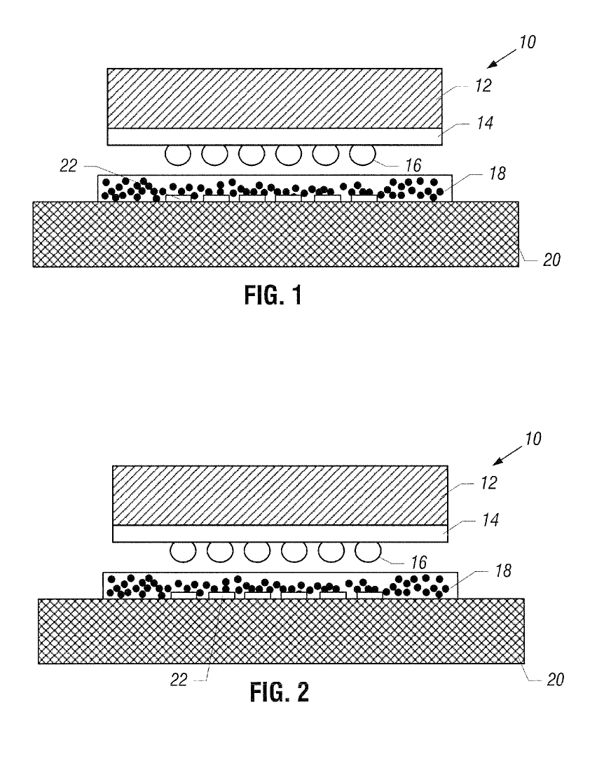

Referring to FIG. 1, an integrated circuit 10, in accordance with one embodiment, has protrusions 16 formed on a lower surface thereof. In one embodiment, the protrusions 16 may be solder balls. An interconnection layer 14 may include metallic layers to make connections between components within the integrated circuit chip 12 and the individual protrusions 16.

The integrated circuit 10 may be generally aligned over a substrate 20. In one embodiment, the substrate 20 includes flat land type contacts 22. A layer of anisotropically conductive adhesive 18 is formed over the pertinent lands 22. In one embodiment, the anisotropically conductive adhesive is an anisotropically conductive film that has been secured over the substrate 20.

As another embodiment, an anisotropically conductive paste may be utilized. Anisotropic paste may be applied by screen printing or other deposition techniques. Alternatively, the structure may be dipped into a bath of anisotropically conductive adhesive. As still another alternative, ink jet printing may be utilized to apply the anisotropically conductive adhesive. Other techniques may be utilized as well.

It is advantageous, in some embodiments, that the anisotropically conductive adhesive 18 be applied to the contacts 22 prior to the time that the integrated circuit 10 is joined to the substrate 20.

Next, as shown in FIG. 2, the protrusions 16 are aligned with the contacts 22 using conventional techniques such as pick and place equipment.

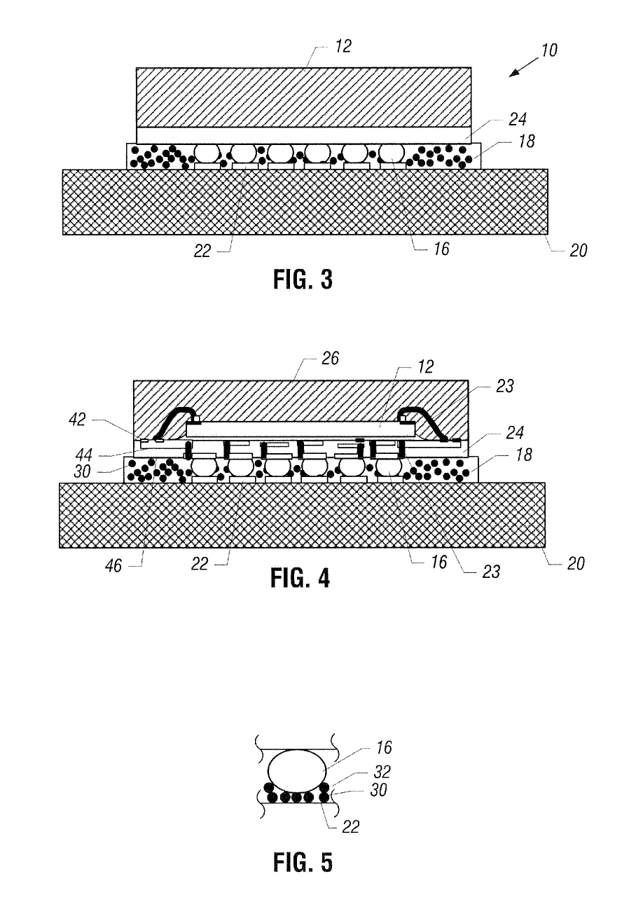

Then, as shown in FIG. 3, compressive pressure is applied between the integrated circuit 10 and the substrate 20. As a result of this compression, the anisotropically conductive adhesive 18, which was originally non-conductive, becomes conductive. It becomes conductive because the individual metallic particles within the anisotropically conductive adhesive become trapped between the protrusion 16 and the contact 22, as best shown in FIG. 5.

Specifically, the conductive particles 30 become lodged in the interface and remain as a rigid separators between the protrusions 16 and the contacts 22. The surrounding resin 32 extrudes out from between the pressurized, confined interface, leaving only the rigid conductive particles 30 to form the electrically conductive joint between the protrusions 16 and the contacts 22.

In accordance with some embodiments, the particles 30 may be conductive particles having dimensions on the order of two to ten microns. They may be nickel particles in one embodiment. Alternatively, gold-coated, nickel particles may be utilized. As still other examples, a polymer core with a nickel finish may be utilized or, as yet another alternative, a nickel gold finish may be utilized.

The resin material 32 is generally a non-conductive adhesive that is activated at a temperature below 150° C. in less than 15 seconds (or longer at lower temperatures). One suitable resin is acrylic resin using monomers containing an acryloxy group or a methacryloxy group, together with peroxide curing agents, having a viscosity of 10 to 100 Pa·s at room temperature. The cured resin may have a Young's modulus from 500 MPa to 10 GPa, and a coefficient of thermal expansion from 20 ppm to 100 ppm below the glass transition temperature Tg in some embodiments. The acrylic resin may include major components of base resin, curing agents, catalysts and coupling agents. In one embodiment, the concentration of metallic particles within the resin is from about 1 wt % to about 10 wt % of the polymer resin. The adhesive bond may have a die shear strength of greater than 0.5 MPa in one embodiment. As another example, epoxy polymers may also be used.

In some embodiments, the coefficient of thermal expansion of the particles may generally match that of the components to be joined such as the protrusions 16 and the contacts 22.

Without being limited by theory, it is believed that the use of an anisotropically conductive adhesive that is activated at temperatures below 150° C. may result, in some embodiments, in better board level reliability. This may be due to one or more of the reduction in joining temperature, the compliance or resilience of the resin material, the strength of the resin bond, and the conductivity achieved by the particles 30.

Thus, referring to FIG. 4, the structure may include a substrate 20 coupled to an integrated circuit chip 12. In one embodiment, the integrated circuit chip 12 is a phase change memory. Electrical connections may be made from the integrated circuit chip to the substrate 20 by attaching the integrated circuit chip 12 to a first surface 42 of an interposer 24, wherein the interposer has at least one routing trace 44 extending from said interposer first surface 42 to an opposing interposer second surface 46. Electrical connections are formed between the integrated circuit chip 12 to at least one interposer routing trace 44 on the interposer first surface 42, such as through wire bonds 23. Electrical connections are formed between the routing trace 44 on the interposer second surface 46 and the substrate contacts 22 through the protrusions 16 and the conductive particles 30.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1-8. (canceled)

9. An apparatus comprising:
a substrate; and
an integrated circuit mounted to said substrate by an anisotropically conductive adhesive curable at a temperature of less than 150° C.

10. The apparatus of claim 9 wherein said integrated circuit is a phase change memory.

11. The apparatus of claim 9 wherein conductive adhesive includes metallic particles embedded in polymer resin.

12. The apparatus of claim 11 wherein said polymer resin includes acrylic resin.

13. The apparatus of claim 12 wherein said particles of have a dimension of from two to ten microns.

14. The apparatus of claim 11 wherein said metallic particles comprise from 1 to 10 weight percent of said resin.

15. The apparatus of claim 9 wherein said adhesive includes a resin having a Young's modulus of from 500 MPa to 10 GPa.

16. The apparatus of claim 15 wherein said resin has a viscosity, prior to curing, of from 10 to 100 Pa.

17. The apparatus of claim 9 wherein said adhesive is situated between said integrated circuit and said substrate.

18. The apparatus of claim 11 wherein said resin includes acrylic polymer.

19. The apparatus of claim 11 wherein said resin includes epoxy.

20. The apparatus of claim 9 wherein said adhesive forms a bond having a shear strength greater than 0.5 MPa.
